(19) United States
(12) Patent Application Publication
(10) Pub. No.: US 2008/0036512 A1
(43) Pub. Date: Feb. 14, 2008

(54) SIGNAL DELAY CIRCUIT AND DRIVER CIRCUIT, SIGNAL TRANSMISSION MODULE, AND SIGNAL TRANSMISSION SYSTEM USING SIGNAL DELAY CIRCUIT

(76) Inventors: Keiichi Yamamoto, Yamato (JP); Norio Chujo, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/834,714

(22) Filed: Aug. 7, 2007

(30) Foreign Application Priority Data
Aug. 8, 2006 (JP) 2006-215818

(51) Int. Cl. H03K 5/14; H03H 11/26; H03K 3/03

(52) U.S. Cl. 327/155; 327/269; 327/281; 331/57

(57) ABSTRACT

A signal delay circuit includes: a first inverter circuit; a second inverter circuit connected to an output terminal of the first inverter; and a feedback circuit extending from an output terminal of the second inverter to its input terminal. A delay time of the first inverter circuit is adjusted by controlling the amount of feedback through the feedback circuit. Here, the feedback circuit is formed by MOS transistors and the delay time is adjusted by controlling the gate voltages of the MOS transistors. The feedback amount is adjusted in relation to a variation in a power supply voltage and a variation in the delay time of the signal delay circuit is suppressed.

### CLAIM OF PRIORITY

The present application claims priority from Japanese application serial no. JP 2006-215818, filed on Aug. 8, 2006, the content of which is hereby incorporated by reference into this application.

### BACKGROUND OF THE INVENTION

The present invention relates to a signal delay circuit capable of adjusting a delay time of a signal to be transmitted and a driver circuit, a signal transmission module, and a signal transmission system using the signal delay circuit.

As signal transmission speed in computers and communication devices becomes higher and higher, increase or variation in signal delay time across a circuit board on which a transmission path is formed presents a problem. When arithmetic processing is performed with data signals carried through a plurality of transmission paths, timed transmissions of the signals on these paths must be performed for arithmetic operation. A signal delay circuit is often formed by a CMOS inverter and its delay time largely varies depending on a power supply voltage. Because of these matters, a means for adjusting a delay time of a transmission signal is required. Heretofore, delay time adjustment methods such as those mentioned below have been proposed.

Japanese Patent Application Laid-Open Publication No. S61-109312 discloses a method for adjusting signal charging/discharging time with a filter having a resistor and a capacitor. In this method, to a node of a CMOS inverter that constitutes a delay circuit, an active element (MOSFET transistor) whose effective resistance value varies with a power supply voltage and a capacitor are connected in series, with the result that variation in the power supply voltage does not affect the delay time of the delay circuit.

Japanese Patent Application Laid-Open Publication No. H10-233665 discloses a method for switching between a plurality of delay elements having different delay times by a switching means. This method is intended to compensate for a delay time variation in relation to a change in a power supply voltage by operating the switching means depending on the power supply voltage.

Japanese Patent Application Laid-Open Publication No. 2000-59184 describes reducing a delay time variation by inserting a MOSFET in the middle of a power supply path to suppress a variation in a voltage applied to a CMOS inverter.

### SUMMARY OF THE INVENTION

In the delay time adjustment method using a resistor/capacitor type circuit as described in the above-mentioned Japanese Patent Application Laid-Open Publication No. S61-109312, it is difficult to transmit a signal at a high speed. The reason for this is explained using drawings. FIG. 27 shows the principle of a delay time adjustment circuit of a resistor/capacitor type. A delay circuit is formed by a CMOS inverter having Mp1 and Mn1 and a grounded capacitor C1 is connected to a node of the CMOS inverter. By changing the capacitance of the capacitor C1 (or turning the capacitor ON/OFF), the time for charging/discharging the capacitor C1 is changed. FIGS. 28A and 28B show the waveforms of an input voltage V1 and an output voltage V2 (applied to the terminal of the capacitor C1) of the CMOS inverter in FIG. 27. FIG. 28A shows a relationship between the input voltage V1 and the output voltage V2. The descent gradient of the output voltage V2 changes and the delay time determined by a point of intersection of the descent gradient with a threshold changes from T1 to T2. That is, the delay time is adjusted by changing a charging/discharging time constant to make the descent gradient of the signal waveform less steep. FIG. 28B shows the waveform of the output signal V2 when a pulse signal is input as the input signal V1. In the case of operation with a high-speed signal having a short pulse width such as, for example, 10 Gbps, V2 is transmitted in the pulse form if the delay time is short, but it happens that the waveform of V2 does not rise to the threshold level if the delay time is long. As a result, the following problem arises: a signal to be transmitted as a pulse disappears, that is, a signal transmission failure occurs.

The method of switching over between the delay elements described in the above-mentioned Japanese Patent Application Laid-Open Publication No. H10-233665, the switchover is made by selecting one of a plurality of fixed delay times. Therefore, this method is unable to change the delay time continuously and has a difficulty in adjusting the delay time with a high precision.

Since the countermeasure against variation in the power supply voltage described in the above-mentioned Japanese Patent Application Laid-Open Publication No. 2000-59184 utilizes an arrangement in which the MOSFET is inserted in the middle of the power supply path, a voltage drop occurs across the MOSFET. Therefore, the supply voltage must be high enough to provide some margin. Consequently, it is difficult to adopt this arrangement in a high-speed communication circuit or the like which is driven on a low supply voltage on the order of 1 V, for example.

The present invention provides a solution to the above-noted problems and provides a circuit capable of making delay time adjustment continuously for a high-speed signal. The present invention also provides a circuit capable of suppressing delay time variation even if the power supply voltage is low.

A signal delay circuit of the present invention is configured including a first inverter circuit and a second inverter circuit connected to an output terminal of the first inverter, the signal delay circuit including a feedback circuit extending from an output terminal of the second inverter circuit to an input terminal of the second inverter circuit, wherein a delay time of the first inverter circuit is adjusted by controlling the amount of feedback through the feedback circuit.

Preferably, the first and second inverter circuits are formed by CMOS transistors, the feedback circuit is formed by MOS transistors, and the delay time of the first inverter circuit is adjusted by controlling gate voltages of the MOS transistors, thus controlling the amount of feedback through the feedback circuit.

The signal delay circuit further includes a control circuit for controlling the feedback circuit, wherein the control circuit adjusts the amount of feedback through the feedback circuit in relation to a variation in a power supply voltage and suppresses a variation in the delay time of the signal delay circuit.

An oscillation circuit of the present invention is configured including a plurality of signal delay circuits configured as described above connected in series, whose output is fed back to an input terminal of the oscillation circuit. By controlling the amount of feedback through the feedback circuit, a delay time of each signal delay circuit is adjusted and an oscillation frequency of the oscillation circuit is controlled.

A driver circuit of the present invention includes a timing adjustment circuit that adjusts transmission timing and a signal delay circuit configured as described above that adjusts a delay time of a signal from the timing adjustment circuit, wherein a delay time of a signal to be transmitted is adjusted by controlling the amount of feedback through the feedback circuit in the signal delay circuit.

A signal transmission module of the present invention includes a driver circuit mounted on a circuit board and a receiver circuit mounted on a circuit board, a signal being transmitted from the driver circuit to the receiver circuit via a signal transmission pat. The driver circuit includes a signal delay circuit configured as described above that adjusts a delay time of a signal to be transmitted. A delay time of a signal to be transmitted through the signal transmission path is adjusted by controlling the amount of feedback through the feedback circuit in the signal delay circuit.

A computing system of the present invention includes a plurality of computers interconnected via a transmission medium, wherein one computer can transmit and receive data signals to/from another computer. Each computer includes an arithmetic unit, a storage unit, a logic unit, a driver circuit for transmitting data signals, and a receiver circuit for receiving data signals. The driver circuit includes a signal delay circuit configured as described above that adjusts a delay time of a data signal to be transmitted, wherein a delay time of a signal to be transmitted through the transmission medium is adjusted by controlling the amount of feedback through the feedback circuit in the signal delay circuit.

A data exchange system of the present invention includes a plurality of communication devices interconnected via a transmission medium, wherein one device can transmit and receive data signals to/from another device. Each communication device includes an input/output unit that is connected to an external network, a storage unit, a logic unit, a driver circuit for transmitting data signals, and a receiver circuit for receiving data signals. The driver circuit includes a signal delay circuit configured as described above that adjusts a delay time of a data signal to be transmitted, wherein a delay time of a signal to be transmitted through the transmission medium is adjusted by controlling the amount of feedback through the feedback circuit in the signal delay circuit.

### BRIEF DESCRIPTION OF THE DRAWINGS

These and other objects, features and advantages of the invention will be apparent from the following particular description of preferred embodiments of the invention, as illustrated in the accompanying drawings.

FIG. 1 is a circuit configuration diagram showing one embodiment of a signal delay circuit according to the present invention;

FIG. 2 is a graph to explain the principle of delay time adjustment by a feedback resistance method;

FIG. 3 is a graph showing an example of a relationship between feedback resistance and signal delay time;

FIGS. 4A to 4C show results of output waveforms obtained by the circuit simulator (SPICE), presenting delay time adjusted waveforms;

FIG. 5 is a circuit configuration diagram showing another embodiment of a signal delay circuit according to the present invention;

FIG. 6 is a circuit configuration diagram showing another embodiment of a signal delay circuit according to the present invention;

FIG. 7 is a circuit configuration diagram showing another embodiment of a signal delay circuit according to the present invention;

FIG. 8 is a circuit configuration diagram showing another embodiment of a signal delay circuit according to the present invention;

FIG. 9 is a configuration diagram in which a delay time control circuit in FIG. 8 is shown specifically;

FIG. 10 is a configuration diagram showing one embodiment of an oscillation circuit according to the present invention;

FIG. 11 shows an example of a configuration for measuring the delay time of a signal delay circuit, using the oscillation circuit shown in FIG. 10;

FIG. 12 shows another example of a configuration for measuring the delay time of a signal delay circuit, using the oscillation circuit shown in FIG. 10;

FIG. 13 is a configuration diagram showing one embodiment of a PLL circuit utilizing the oscillation circuit shown in FIG. 10;

FIG. 14 is a configuration diagram showing one embodiment of a signal delay circuit utilizing the oscillation circuit shown in FIG. 10;

FIG. 15 is a configuration diagram showing one embodiment of a driver circuit according to the present invention;

FIG. 16 is a configuration diagram showing another embodiment of a driver according to the present invention;

FIG. 17 is a configuration diagram showing one embodiment of a transmission circuit utilizing the PLL circuit shown in FIG. 13;

FIGS. 18A and 18B show a graphic representation of an effect of delay time adjustment made by the driver circuit of the present embodiment;

FIG. 19 is a perspective diagram showing one embodiment of a signal transmission module according to the present invention;

FIG. 20 is a perspective diagram showing another embodiment of a signal transmission module according to the present invention;

FIG. 21 is a perspective diagram showing another embodiment of a signal transmission module according to the present invention;

FIG. 22 is a perspective diagram showing another embodiment of a signal transmission module according to the present invention;

FIG. 23 is a perspective diagram showing another embodiment of a signal transmission module according to the present invention;

FIG. 24 is a perspective diagram showing another embodiment of a signal transmission module according to the present invention;

FIG. 25 is a configuration diagram showing one embodiment of a computing system according to the present invention;

FIG. 26 is a configuration diagram showing one embodiment of a data exchange system according to the present invention;

FIG. 27 is a diagram showing the principle of a delay time adjustment circuit of a resistor/capacitor type of related art;

FIGS. 28A and 28B show the waveforms of input voltage and output voltage in FIG. 27;

FIG. 29 is a configuration diagram showing one embodiment of an IC circuit with a pulse generating function according to the present invention; and

FIG. 30 is a configuration diagram showing another embodiment of an IC circuit with a pulse generating function according to the present invention.

### DESCRIPTION OF THE PREFERRED EMBODIMENTS

Embodiments of a signal delay circuit according to the present invention and a driver circuit, a signal transmission module, and a signal transmission system using the signal delay circuit will be described hereinafter by way of the drawings.

### Embodiment 1

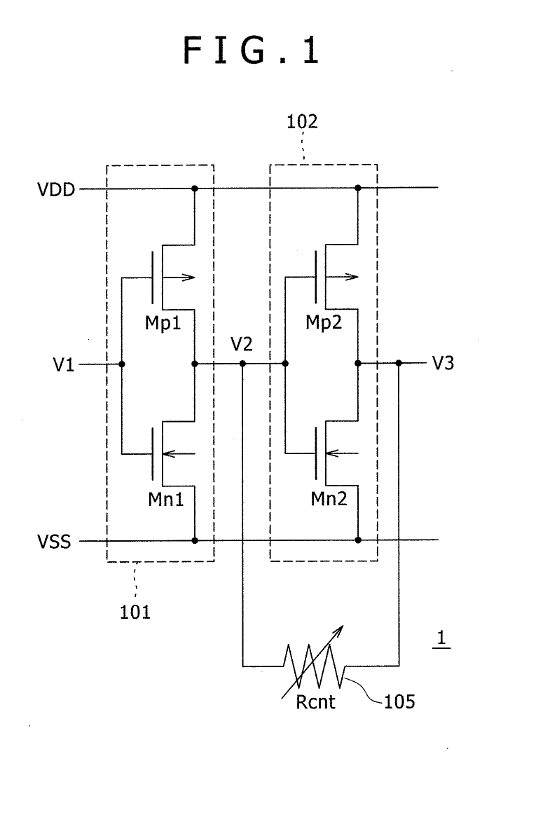

FIG. 1 is a circuit configuration diagram showing one embodiment of a signal delay circuit according to the present invention. This signal delay circuit 1 is configured such that a first inverter circuit 101 and a second inverter circuit 102 are connected and a variable resistor (Rcnt) 105 is installed on a feedback path from the output terminal V3 of the second inverter circuit 102 to its input terminal V2. This configuration is hereinafter referred to as a “feedback resistance method”. The first and second inverter circuits 101, 102 are CMOS inverter structures in each of which a p-MOS transistor (Mp1, Mp2) and an n-MOS transistor (Mn1, Mn2) are coupled to complement each other. A power supply voltage is supplied to VDD, V1 is an input signal terminal, and V3 is an output signal terminal.

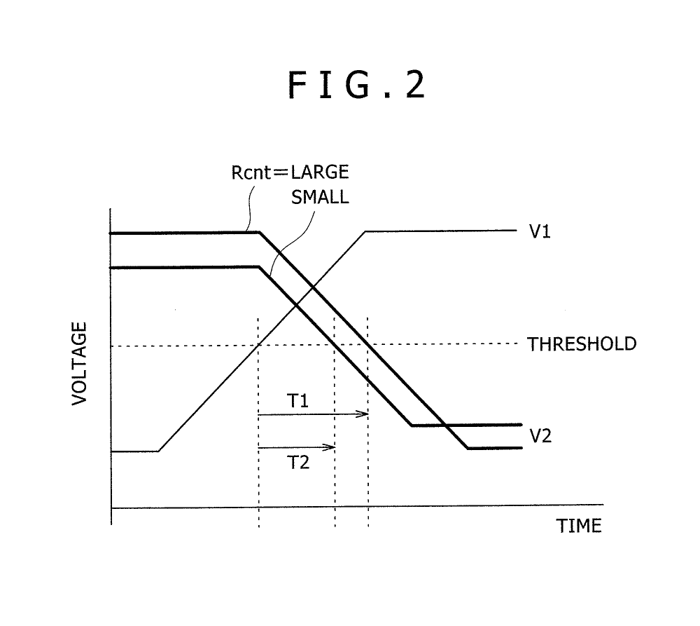

FIG. 2 is a graph to explain the principle of delay time adjustment by the feedback resistance method of the present embodiment. This graph shows the waveforms of the voltages of the input terminal V1 and the output terminal V2 of the first inverter circuit 101 and indicates a time delay between the timing of rise of the former voltage and the timing of fall of the latter voltage.

When the feedback resistance Rcnt is large (or zero), a time difference T1 between the timing at which the rising voltage waveform of V1 crosses the threshold level and the timing at which the falling voltage waveform of V2 crosses the threshold level is determined based on the switching characteristic of the first inverter 101. This time difference is a signal delay time across the first inverter circuit 101.

On the other hand, when the feedback resistance Rcnt is small, the voltage at the output terminal V3 of the second inverter circuit is fed back to the terminal V2. Here, because the terminals V2 and V3 have opposite signal polarities (Hi/Low states of voltage), the amplitude of the voltage at V2 decreases when receiving the feedback voltage from V3. By this decrease in the amplitude, the timing at which the falling voltage waveform of V2 crosses the threshold level becomes earlier than when the feedback resistance Rcnt is large (or zero). In consequence, the signal delay time across the first inverter circuit 101 changes to T2 that is shorter than the above time T1. In this way, the signal delay time can be adjusted in relation to the feedback resistance Rcnt.

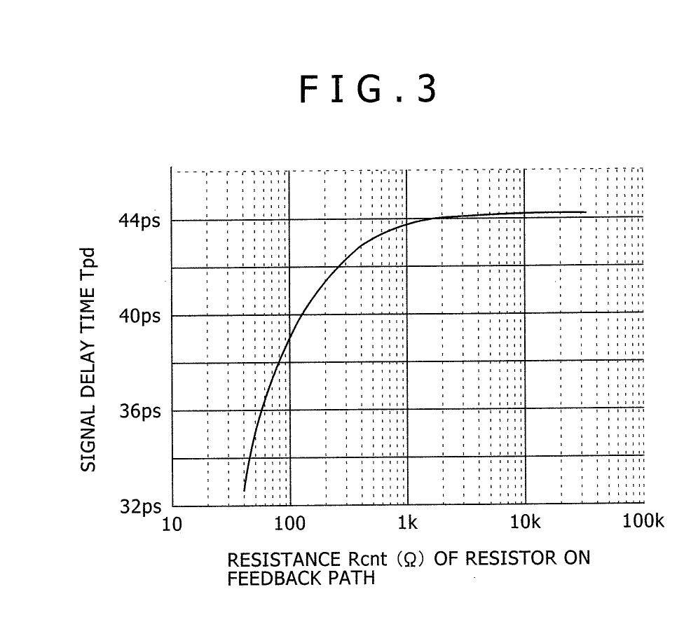

FIG. 3 is a graph showing an example of a relationship between feedback resistance and signal delay time, changed by the feedback resistance method of the present invention. This graph is a result of simulation performed by a circuit simulator (SPICE). It can be seen from this graph that the smaller the feedback resistance Rcnt, the signal delay time Tpd will be shorter. That is, the signal delay time is shortened by increasing the feedback amount. The signal delay time Tpd can be adjusted continuously in relation to the resistance Rcnt of the resistor on the feedback path.

Here, signal waveform profiles after a delay are presented, when the signal delay time is adjusted by the feedback resistance method of the present invention.

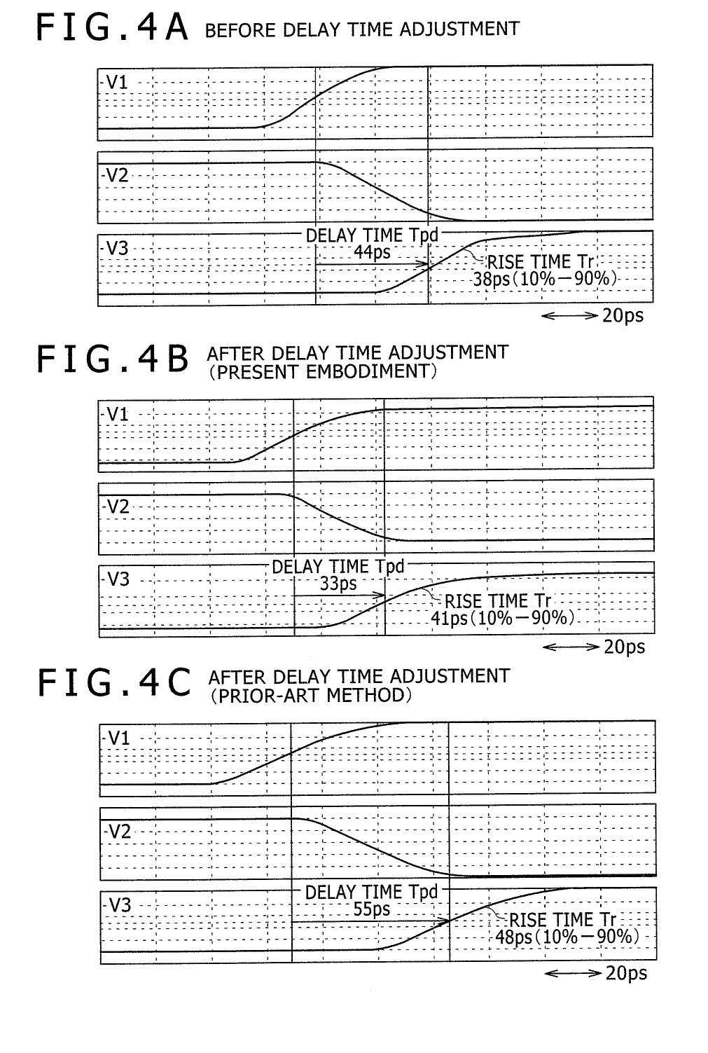

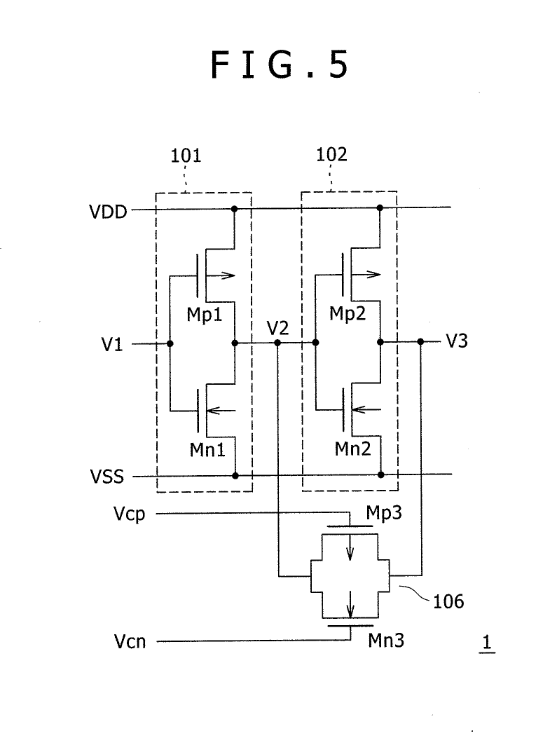

FIGS. 4A to 4C show results of output waveforms obtained by the circuit simulator (SPICE), presenting delay time adjusted waveforms. FIG. 4A shows the waveforms before delay time adjustment, FIG. 4B shows the waveforms after the delay time adjustment by the feedback resistance method of the present invention, and FIG. 4C shows the waveforms after a delay time adjustment by the resistor/capacitor type method of related art, presented for comparison purposes.

In FIG. 4A, a delay time Tpd of 44 ps takes place between the input V1 and the output V3 before delay time adjustment. The rise time (the time during which the amplitude level rises from 10% up to 90%) Tr of the output V3 representing an ascent gradient of the waveform of V3 is 38 ps. In FIG. 4B, when the delay time Tpd is adjusted to 33 ps (a time difference of 11 ps from the delay time in FIG. 4A) by the feedback resistance method, the rise time Tr of the output V3 waveform becomes 41 ps. In FIG. 4C, when the delay time Tpd is adjusted to 55 ps (a time difference of 11 ps from the delay time in FIG. 4A) by the resistor/capacitor type method of related art, the rise time Tr of the output V3 waveform becomes 48 ps.

The waveform rise time Tr to obtain a comparable time difference of 11 ps in delay time is Tr=41 ps for the feedback resistance method in FIG. 4B and Tr=48 ps for the resistor/capacitor type method in FIG. 4C. Thus, according to the feedback resistance method of the present embodiment, the ascent gradient of the output waveform after delay time adjustment does not become less steep and this indicates that this delay time adjustment method is suitable for transmission of a high-speed signal with a short pulse width.

The resistor/capacitor type method of related art and the feedback resistance method of the present embodiment both make delay time adjustment but in opposite time directions: i.e., the delay time is adjusted to be longer by the related art method, while the delay time is adjusted to be shorter by the present embodiment method. Therefore, the comparison between the above output waveforms in both cases was performed in terms of time difference of the adjusted delay time from the delay time before being adjusted. In a high-speed signal transmission circuit, it is generally undesirable to lengthen the delay time, resulting in signal quality degradation. According to the feedback resistance method of the present embodiment, the delay time can be adjusted to be shorter at all times and, therefore, this method is effective for applications such as communication devices for which a shorter signal processing time is required.

In the present embodiment, as described above, the output of the inverter circuit is fed back to its input and the signal delay time can be adjusted continuously by adjusting the amount of the feedback. Because, by this adjustment, the ascent gradient of the output waveform does not become less steep, this delay adjustment method can be applied to high-speed communication of a signal with a short pulse width without problems.

### Embodiment 2

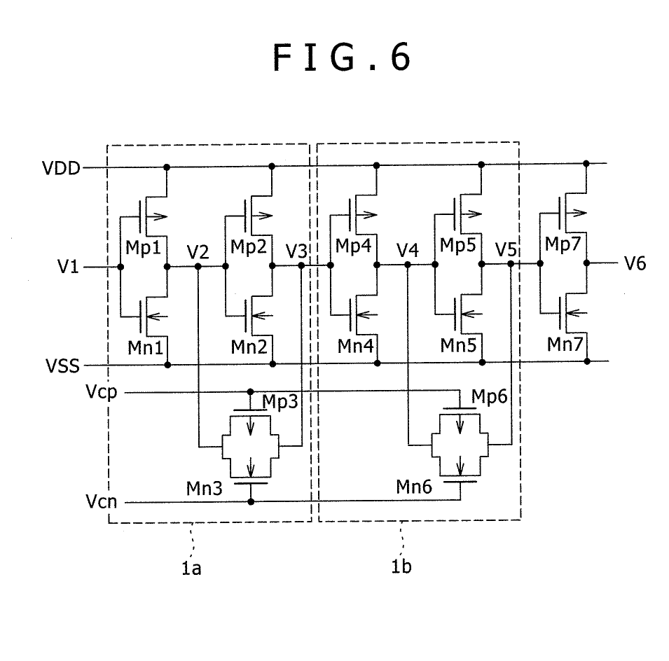

FIG. 5 is a circuit configuration diagram showing another embodiment of a signal delay circuit according to the present invention. In the signal delay circuit 1 of the present embodiment, configured and shown here as an example, a couple of MOS transistor elements (Mp3 and Mn3) 106 is installed as the variable resistor (Rcnt) in the foregoing Embodiment 1 (FIG. 1). In this circuit, the effective resistance value, or the amount of feedback is controlled by controlling the gate voltages (Vcp and Vcn) of the MOS transistor elements 106. According to the present embodiment, delay time adjustment operation can be performed in the same way as in the foregoing Embodiment 1. Moreover, the feedback resistance is formed by the couple of MOS transistor elements 106 in a complementary manner and therefore, delay time adjustment can be made in a similar fashion for both Hi and Low states of the V3 voltage.

### Embodiment 3

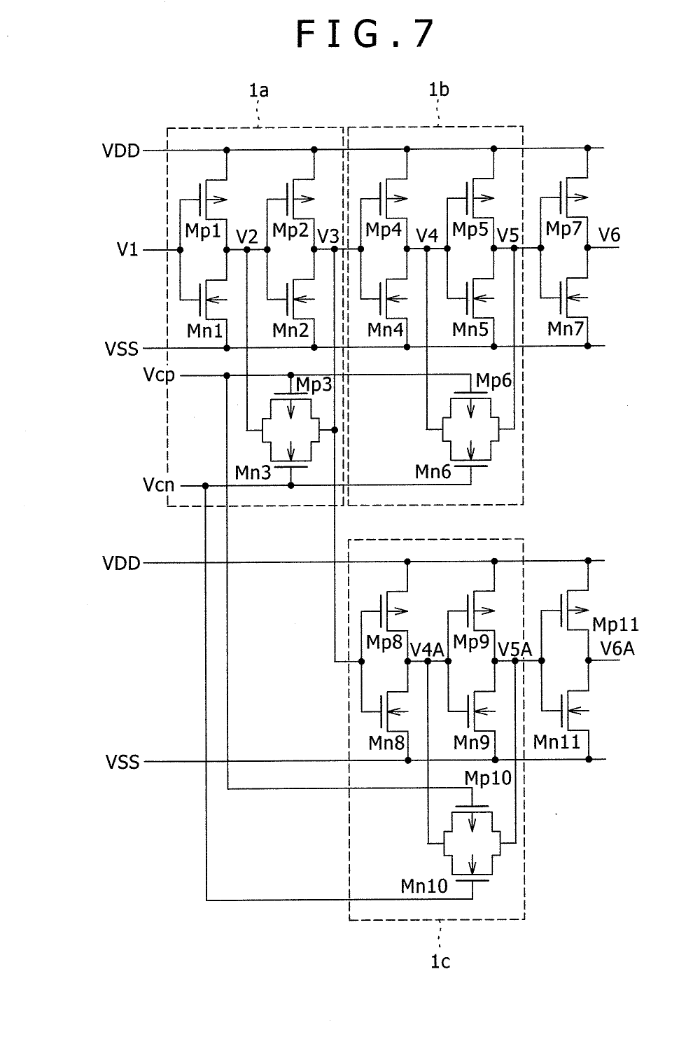

FIG. 6 is a circuit configuration diagram showing another embodiment of a signal delay circuit according to the present invention. In the configuration of the present embodiment, a plurality of signal delay circuits 1 (two signal delay circuits 1a, 1b in this example) according to the foregoing Embodiment 1 or Embodiment 2 are connected in series. Delay time can be adjusted by controlling the amount of feedback of each signal delay circuit 1a, 1b. By connection of multiple stages of signal delay circuits in this way, requirement of a large delay time, of course, can be accommodated and, moreover, the signal rise characteristic (amplification degree) can be made steeper.

Further, FIG. 7 is a circuit configuration diagram showing another embodiment of a signal delay circuit according to the present invention. In the configuration of the present embodiment, a circuit branches off from a terminal V3 in the configuration of FIG. 6 and a further signal delay circuit 1c is connected to the branch. According to this configuration, by adjusting the feedback amounts of the respective signal delay circuits 1a, 1b, 1c, delay time adjusted output signals V6, V6a of a plurality of paths can be generated and supplied. By duplicating such a branch of a signal delay circuit in this way, signals can be supplied to a number of output destinations efficiently.

### Embodiment 4

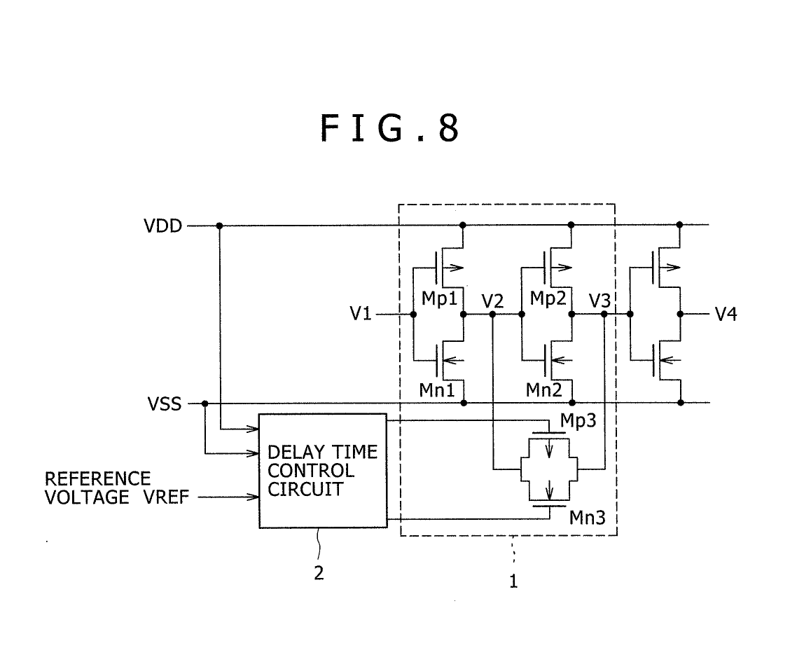

FIG. 8 is a circuit configuration diagram showing another embodiment of a signal delay circuit according to the present invention. In the configuration of the present embodiment, a delay time control circuit 2 is added to the signal delay circuit 1 described in the foregoing Embodiment 2 (FIG. 5). The delay time control circuit 2 controls the feedback amount of the signal delay circuit 1 and, herein, has a function of control so that the delay of the signal delay circuit 1 does not vary even if the power supply voltage VDD varies. That is, the delay time control circuit 2 to which the power supply voltage VDD and a reference voltage VREF are input controls the feedback amount of the signal delay circuit 1, based on the reference voltage VREF value, and adjusts the delay of the signal delay circuit 1. According to this configuration, delay time variation can be suppressed even if the power supply voltage VDD varies and the quality of a transmission signal is improved. In the case of the present embodiment, the delay time control circuit 2 is inserted in parallel with the power supply voltage VDD line and the power supply voltage VDD is applied without a drop to the signal delay circuit 1. Thus, this configuration can be adopted easily even if the power supply voltage VDD is low (e.g., on the order of 1 V).

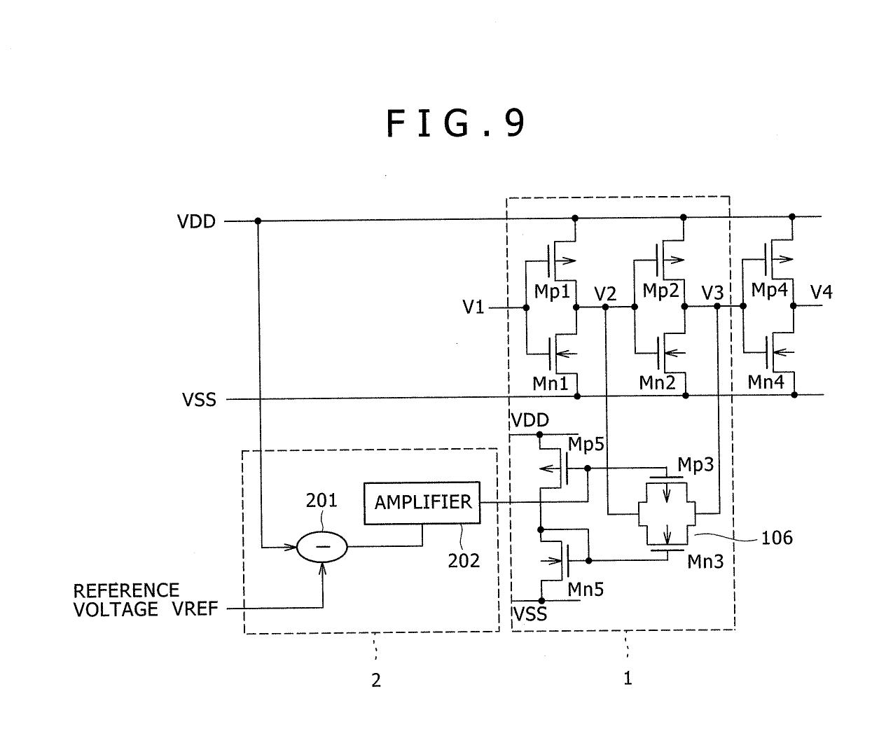

FIG. 9 is a configuration diagram in which the delay time control circuit 2 in the embodiment of FIG. 8 is shown more specifically. The delay time control circuit 2 includes a subtractor 201 for calculating a difference between the power supply voltage VDD and the reference voltage VREF and an amplifier 202 for amplifying a signal corresponding to the difference. Output of the amplifier 202 is supplied to the gate terminals of the MOS transistors 106. According to this configuration, even if the supply voltage VDD deviates off the reference voltage VREF, delay time variation can be suppressed by correcting the gate voltages of the MOS transistors 106.

### Embodiment 5

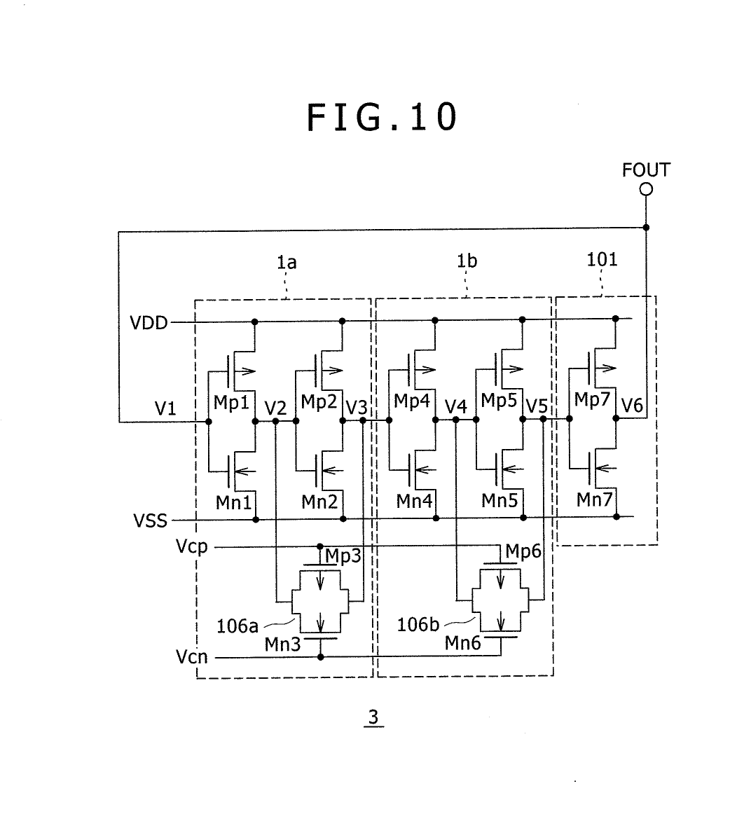

FIG. 10 is a configuration diagram showing one embodiment of an oscillation circuit 3 using a signal delay circuit according to the present invention. The oscillation circuit 3 of the present embodiment is configured such that a plurality of signal delay circuits 1 (two ones 1a and 1b herein) described in the foregoing Embodiment 2 (FIG. 5) are connected in series, a CMOS inverter circuit 101 is connected to the output terminal V5 of the second signal delay circuit 1b, and the output V6 of the inverter circuit 101 is fed back and connected to the input V1 of the first signal delay circuit 1a. This circuit operates as an oscillation circuit, as an odd number of CMOS inverters (five ones herein) are connected in a loop, and its oscillation frequency is determined by signal delay time from the terminal V1 to the terminal V6. Delay time and resulting oscillation frequency can be changed by controlling the gate voltages Vcp and Vnp applied to CMOS transistors 106a and 106b for feedback. Because the delay time is adjusted to be shorter in the signal delay circuits 1a, 1b, as noted above, the oscillation circuit 3 of the present embodiment is capable of outputting an oscillation signal with a higher frequency as compared with conventional oscillation circuits.

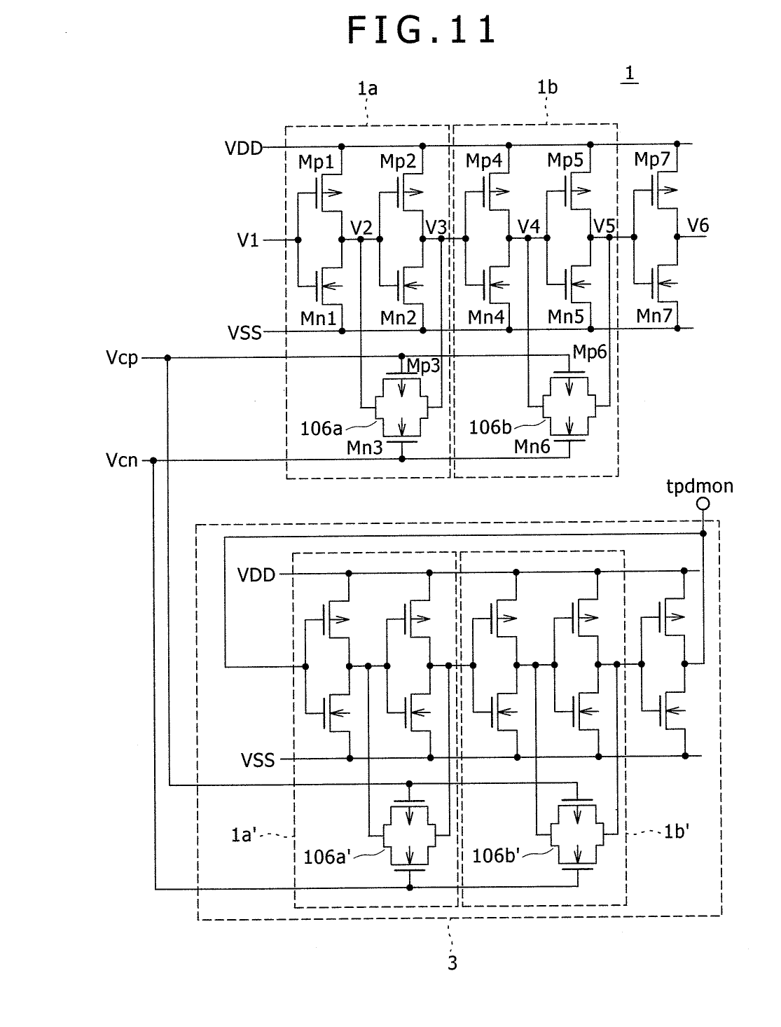

FIG. 11 is a diagram showing an example of a configuration for measuring the delay time of a signal delay circuit, using the oscillation circuit 3 presented in FIG. 10. The signal delay circuit 1 includes two delay circuits 1a, 1b as described in the foregoing Embodiment 1 (FIG. 6) and the oscillation circuit 3 having two delay circuits 1a′, 1b′ presented in FIG. 10 is connected to the signal delay circuit 1. In this case, the signal delay circuit 1 and the oscillation circuit 3 include an equal number of delay circuits. In this configuration, common voltages Vcp, Vcn are applied to the gates of CMOS transistors 106a to 106b′ for feedback in the signal delay circuit 1 and the oscillation circuit 3. This configuration provides one-to-one correspondence between delay time steps in the signal delay circuit 1 and oscillation frequency steps in the oscillation circuit 3. The delay time across the signal delay circuit 1 can be known directly from the oscillation frequency at the output terminal (tpdmon) of the oscillation circuit 3. Frequency division of this oscillation output signal to a low frequency may be applied to make frequency measurements easy, so that the delay time across the signal delay circuit 1 can be known more conveniently.

FIG. 12 is a diagram showing another example of a configuration for measuring the delay time of a signal delay circuit, using the oscillation circuit 3 presented in FIG. 10. The signal delay circuit 1 herein is configured to include two delay circuits 1a, 1b and a delay time control circuit 2 and the oscillation circuit 3 is connected to this signal delay circuit. The delay time control circuit 2 to which the power supply voltage VDD and the reference voltage VREF are input compares these voltages and controls the gate voltages Vcp, Vcn that are common for the signal delay circuit 1 and the oscillation circuit 2. This configuration makes it possible to know the delay time across the signal delay circuit 1 from the oscillation frequency (tpdmon) of the oscillation circuit 3. In addition, for example, this configuration makes it possible to verify a degree of suppression of delay time variation due to a variation in the power supply voltage VDD. When this variation suppression effect is insufficient, operating conditions of the delay time control circuit 2 can be readjusted and set to further reduce delay time variation.

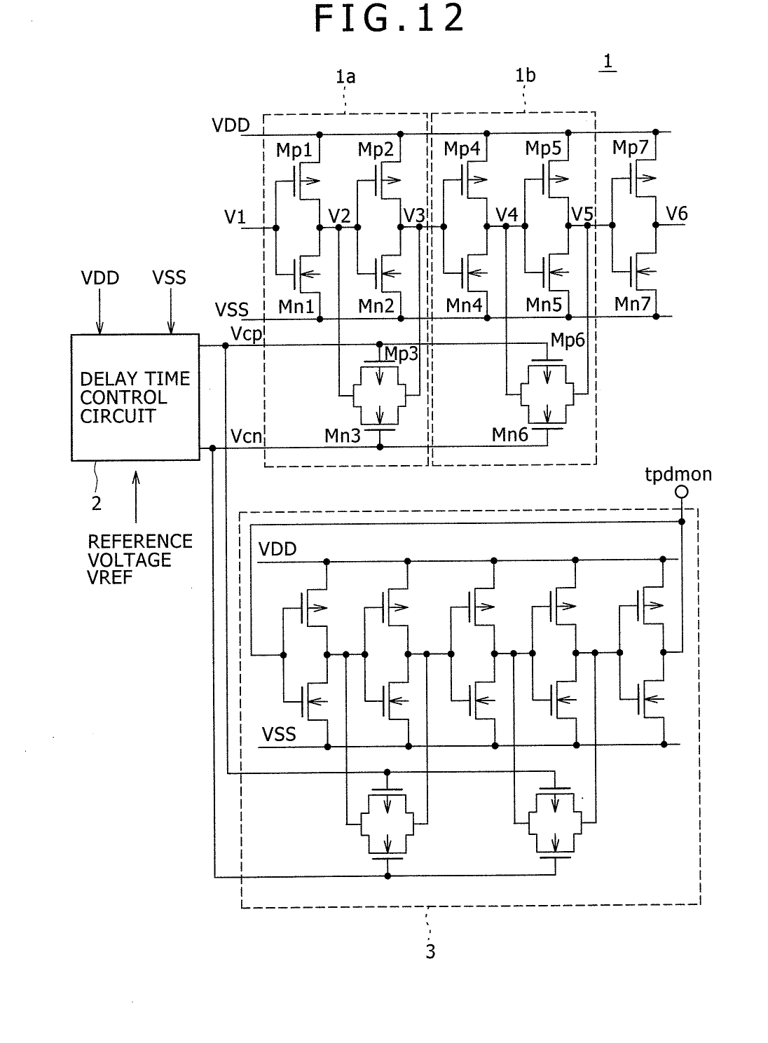

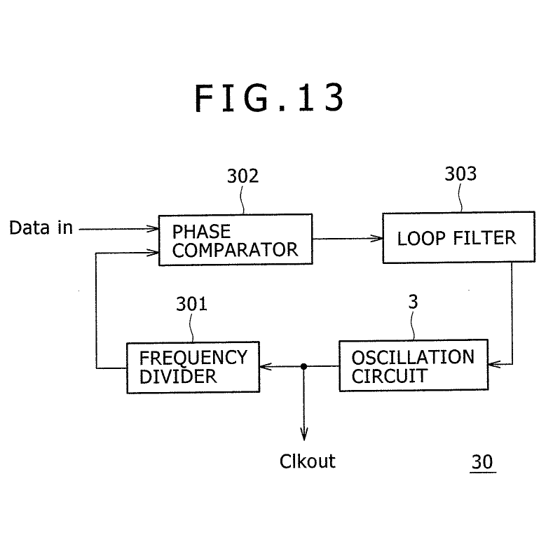

FIG. 13 is a configuration diagram showing one embodiment of a PLL circuit 30 utilizing the oscillation circuit presented in FIG. 10. This PLL circuit 30 is configured including the oscillation circuit 3 presented in FIG. 10, a frequency divider 301, a phase comparator 302, and a loop filter 303, and is capable of outputting a frequency in synchronization with data that is input to the phase comparator 302. In this configuration, because the oscillation circuit 3 is implemented with CMOS transistors, circuit downsizing is possible without requiring provision of an LC resonance circuit and an RC resonance circuit. The oscillation circuit 3 used in this embodiment is capable of outputting an oscillation signal with a higher frequency as compared with conventional oscillation circuits and, therefore, the PLL circuit 30 can handle a higher frequency signal.

FIG. 14 is a configuration diagram showing one embodiment of a signal delay circuit utilizing the oscillation circuit presented in FIG. 10. In the present embodiment, an arrangement as the delay time control circuit 2 for the signal delay circuit 1 of the foregoing Embodiment 4 (FIG. 8) includes two oscillation circuits 3a, 3b as presented in FIG. 10, a phase comparator 211 which compares the oscillation frequencies of signals output by the oscillation circuits, a counter 212 which stores a result of comparison, and a DA converter 213 which provides a control signal (voltage) to the signal delay circuit 1. To one oscillation circuit 3a, the power supply VDD that is common for the signal delay circuit 1 is supplied. The oscillation circuit 3a outputs an oscillation frequency corresponding to a delay time across the signal delay circuit 1. Here, the power supply VDD has a large current capacity, but the power supply voltage varies with a load variation. Consequently, the delay time of the signal delay circuit 1 varies and thus the oscillation frequency of the oscillation circuit 3a changes. To the other oscillation circuit 3b, a stable power supply VDD2 with less power supply variation is supplied. Thus, the oscillation circuit 3b operates to output a constant oscillation frequency. The oscillation frequencies of these two oscillation circuits 3a and 3b are compared by the phase comparator 211 and the DA converter 231 controls the oscillation circuit 3a and the signal delay circuit 1 to equalize the oscillation frequencies. By this control, it is possible to keep a constant delay time, even if the power supply voltage to the signal delay circuit 1 varies. Additionally, because an oscillation frequency corresponding to a delay time is directly measured for comparison, higher precision control becomes possible.

### Embodiment 6

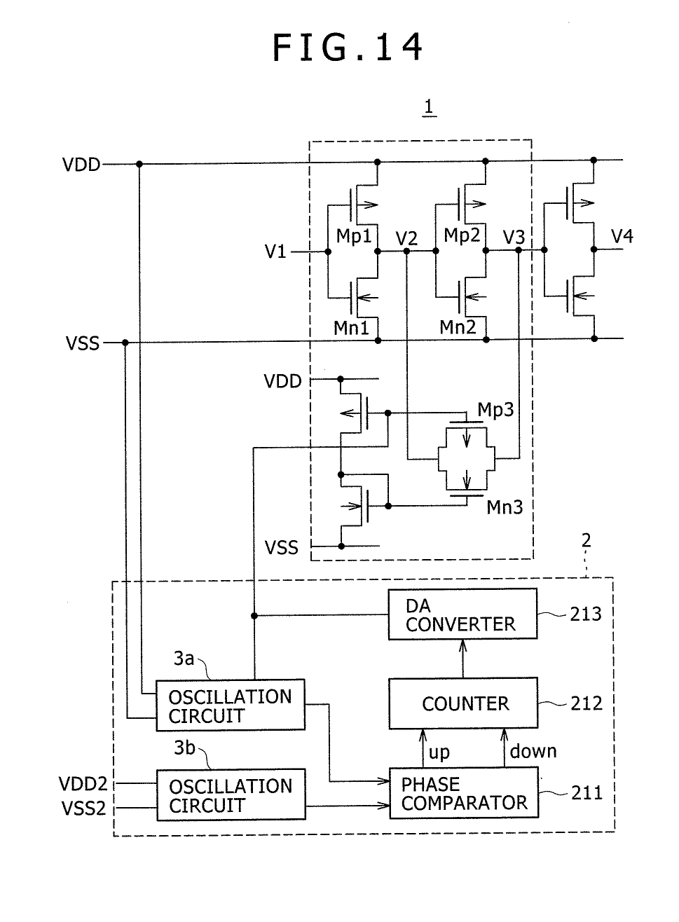

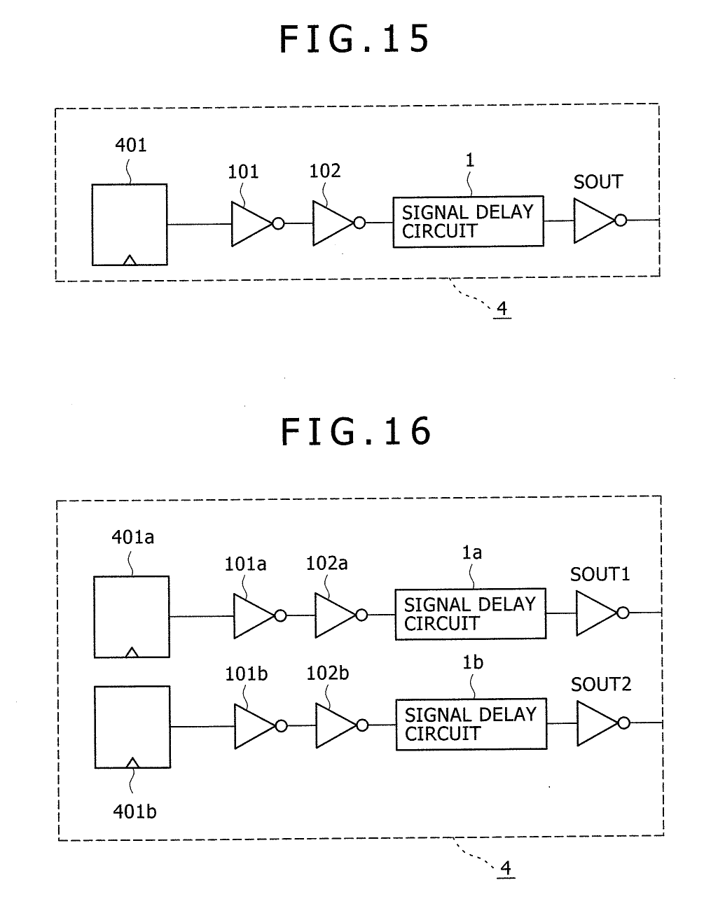

FIG. 15 is a configuration diagram showing one embodiment of a driver circuit utilizing a signal delay circuit of the present invention. The driver circuit 4 of the present embodiment includes a timing adjustment circuit 401, a plurality of inverter circuits 101, 102, and the signal delay circuit 1 as described in the foregoing Embodiments 1 through 4. In this configuration, a signal is input to the driver circuit and its transmission timing is adjusted by the timing adjustment circuit 401, and the signal is transmitted from an output terminal SOUT. This configuration makes it possible to suppress delay time variation of output signals by adjusting the delay time by the signal delay circuit 1, even if a number of inverter circuits 101, 102, . . . are employed in the driver circuit 4 and a larger delay time variation is introduced by these inverter circuits.

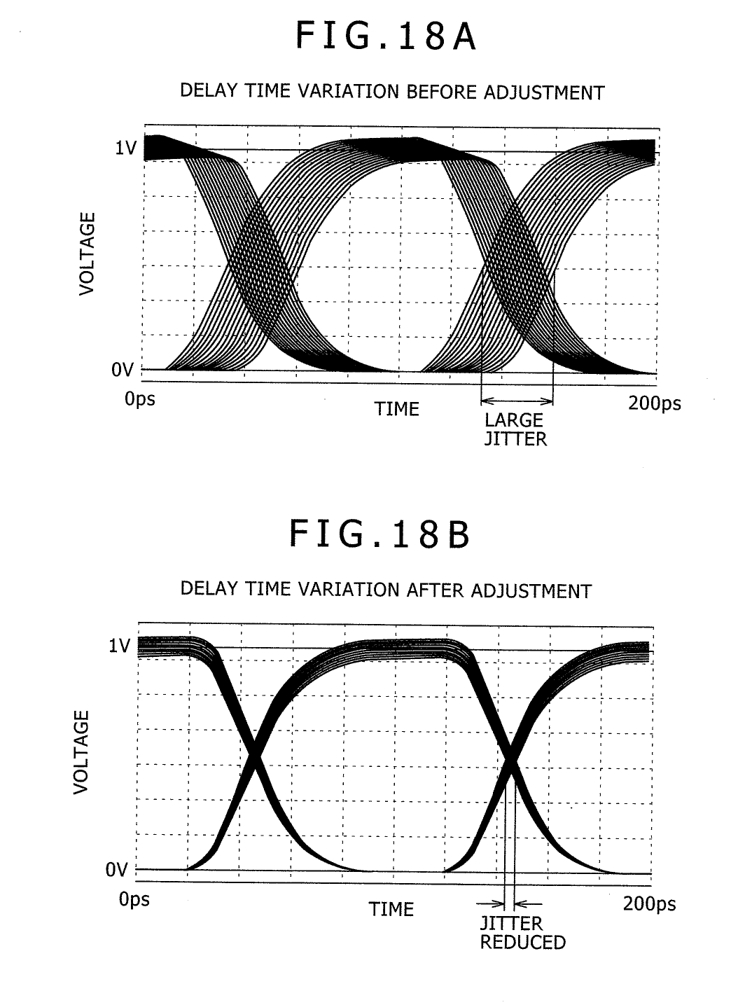

FIGS. 18A and 18B show a graphic representation of an effect of delay time adjustment made by the driver circuit 4 of the present embodiment. Here are shown results of eye patterns of output waveforms obtained by the circuit simulator (SPICE). FIG. 18A shows an eye pattern of an output waveform for which delay time has not been adjusted. FIG. 18B shows an eye pattern of a delay time adjusted output waveform for which time variation has been suppressed. It can be seen from these eye patterns that jitter can be reduced significantly by delay time adjustment made in the driver circuit of the present embodiment. In consequence, the quality of a signal to be transmitted can be improved.

FIG. 16 is a configuration diagram showing another embodiment of a driver circuit utilizing a signal delay circuit of the present invention. This driver circuit 4 is configured including a plurality of driver paths (two paths herein), each consisting of the driver circuit 4 presented in FIG. 15. Two timing adjustment circuits 401a, 402b adjust the timing of each of signals input to the two paths so that these signals are transmitted at the same time. Two signal delay circuits 1a, 1b are capable of controlling their delay times independently. This configuration makes it possible to eliminate a delay time difference between output terminals SOUT1 and SOUT2 by delay adjustments in the signal delay circuits 1a, 1b, even if a local delay time change occurs in the driver circuit 4 and results in a delay time difference between the two paths.

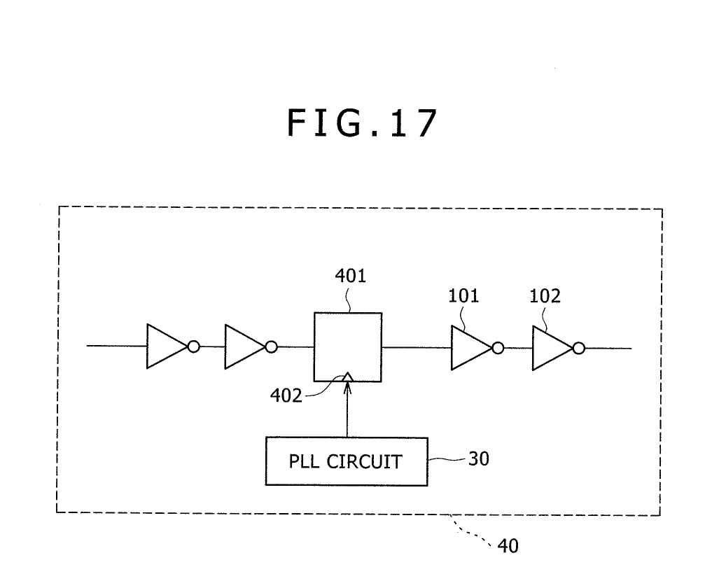

FIG. 17 is a configuration diagram showing one embodiment of a transmission circuit utilizing the PLL circuit 30 presented in FIG. 13. This transmission circuit 40 includes a timing adjustment circuit 401, a plurality of inverter circuits 101, 102, . . . , and the PLL circuit 30. In this configuration, output of the PLL circuit 30 is input to a clock input terminal 402 of the timing adjustment circuit 401. Because this PLL circuit 30 outputs a high-frequency oscillation signal and the circuit can be downsized, as noted above, a smaller transmission circuit 40 suitable for transmission of a high-speed signal can be realized.

### Embodiment 7

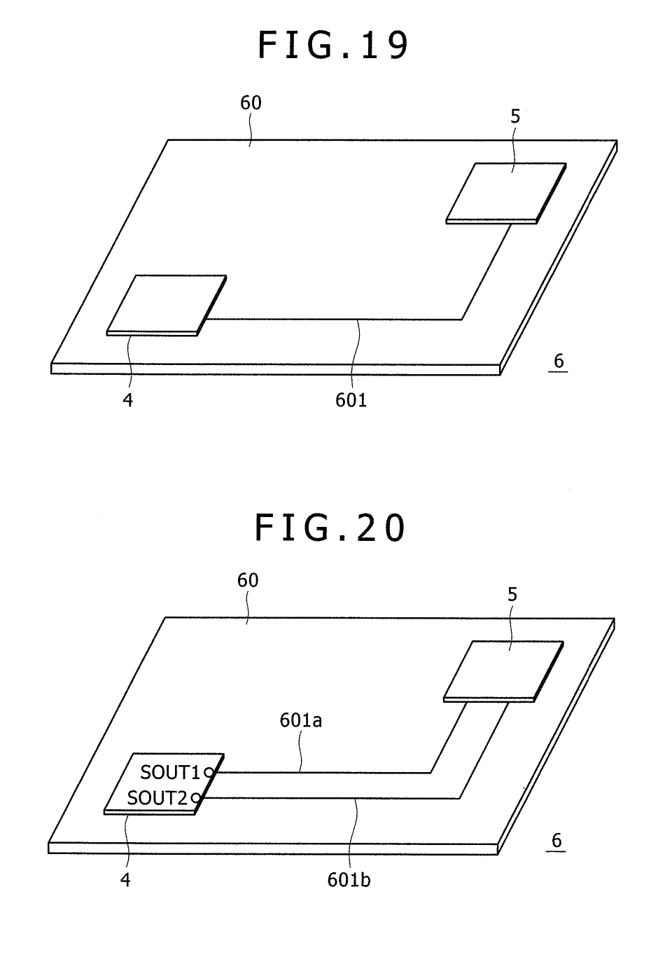

FIG. 19 is a perspective diagram showing one embodiment of a signal transmission module 6 utilizing the driver circuit 4 as described in the foregoing Embodiment 6 (FIG. 15). The signal transmission module 6 includes the following components mounted on a circuit board 60: the driver circuit 4 for transmitting a signal, a receiver circuit 5 for receiving a signal, and a signal transmission path 601 wired therebetween. When a signal is transmitted from the driver circuit 4 to the receiver circuit 5, the signal quality may be degraded by several factors. To lengthen the distance of transmission, the amount of signal degradation due to the respective factors must be reduced. The driver circuit 4 in the present embodiment is capable of reducing jitter by suppressing delay time variation, as noted above, and improves the quality of transmission signals. Therefore, with the signal transmission module 6 utilizing this driver circuit 4, it is possible to lengthen the distance of transmission through the signal transmission path 601, as compared with a similar module using a conventional driver circuit.

In the signal transmission module that transmits a signal using the driver circuit 4 and the receiver circuit 5, these components are used with other components which are not shown in FIG. 19, such as a CDR circuit which regenerates a clock from data, a DEMUX circuit which decreases a signal rate, or a MUX circuit which increases a signal rate.

FIG. 20 is a perspective diagram showing another embodiment of a signal transmission module 6 utilizing the driver circuit 4 presented in the foregoing FIG. 16. This driver circuit 4 transmits signals on a plurality of paths (two paths herein) and the signals are transmitted through a plurality of signal transmission paths 601a, 601b and received by the receiver circuit 5.

Here, if the signal transmission paths 601a, 601b differ in terms of transmission distance, wiring dimensions, or material properties, a time difference occurs between the transmissions on these paths. For example, if one signal is transmitted as a differential signal of the multiple paths, this time difference results in signal quality degradation. This posed a problem in which the transmission distance cannot be lengthened.

The driver circuit 4 in the present embodiment is capable of adjusting a time difference between the transmission signals from the output terminals SOUT1, SOUT2, as noted above. By using this function, it is possible to absorb a time difference occurring between the signal transmissions on the signal transmission paths 601a, 601b and eliminate or reduce a time difference when the respective signals are received by the receiver circuit 5. Therefore, with the signal transmission module 6 utilizing this driver circuit 4, it is possible to lengthen the distance of transmission through the signal transmission paths 601a, 601b, as compared with a similar module using a conventional driver circuit.

The configurations shown in FIG. 19 and FIG. 20 may be combined for use and it is thereby possible to further lengthen the distance of transmission. The circuit board 60 on which the driver circuit and the receiver circuit are mounted may be a signal package or a semiconductor substrate.

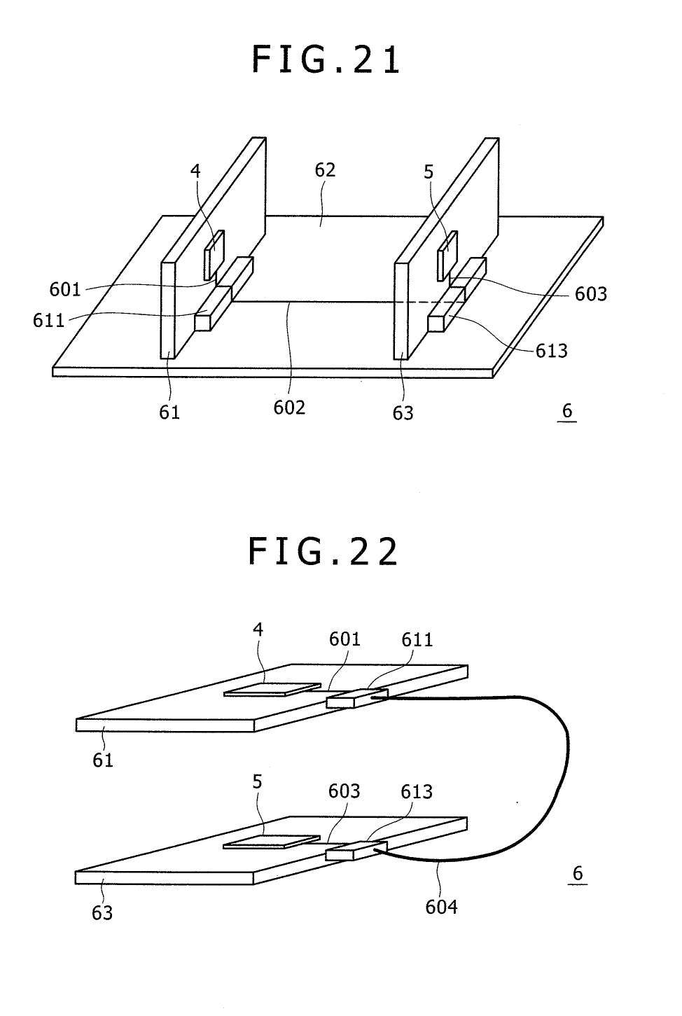

FIG. 21 is a perspective diagram showing another embodiment of a signal transmission module 6 utilizing any driver circuit 4 as described in the foregoing Embodiment 6. The module shown here is made up of three separate circuit boards: a board 61 on which the driver circuit 4 is mounted, a board 62 on which the signal transmission path 602 is wired, and a board 63 on which the receiver circuit is mounted. This module has a solid structure in which the board 61 and the board 63 are set substantially upright on the surface of the board 62. Signal transmission paths 601, 602, 603 on each board are connected via connectors 611, 613. According to this embodiment, it is possible not only lengthen the distance of transmission through the signal transmission path, as is the case for the foregoing embodiment, but also improve the integration degree when many circuits are mounted by virtue of the solid structure having separate boards.

Further, FIG. 22 is a perspective diagram showing another embodiment of a signal transmission module 6 utilizing any driver circuit 4 as described in the foregoing Embodiment 6. Here, a cable 604 is used as the signal transmission path. The board 61 on which the driver circuit 4 is mounted and the board 63 on which the receiver circuit 5 is mounted are connected by the cable 604. According to this embodiment, it is possible not only lengthen the distance of transmission through the signal transmission path, as is the case for the foregoing embodiment, but also freely move or relocate the board 61 and the board 63 by using the cable 604 as the transmission path.

Further, FIG. 23 is a perspective diagram showing another embodiment of a signal transmission module 6 utilizing any driver circuit 4 as described in the foregoing Embodiment 6. Here, an optical transmission medium 605 which is particularly a cable is used as the signal transmission path. The board 61 on which the driver circuit 4 is mounted and the board 63 on which the receiver circuit 5 is mounted are connected by the optical transmission medium 605. According to this embodiment, it is possible not only lengthen the distance of transmission through the signal transmission path, as is the case for the foregoing embodiment, but also transmit a signal at a higher rate by using the optical transmission medium as the transmission path.

The optical transmission medium may be embedded in the boards, instead of using the cable extending in space. In other words, in each embodiment shown in the foregoing FIGS. 19, 20, and 21, the signal transmission module may be configured using the optical transmission medium as the signal transmission path.

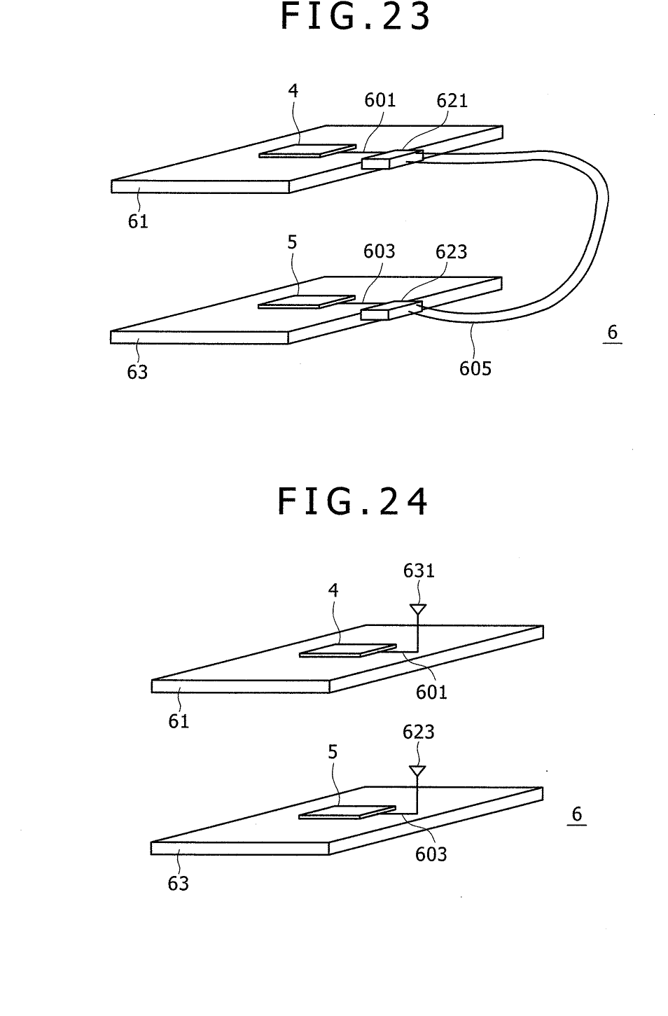

Further, FIG. 24 is a perspective diagram showing another embodiment of a signal transmission module 6 utilizing any driver circuit 4 as described in the foregoing Embodiment 6. Here, radio waves are used for signal transmission. Therefore, a transmitting antenna 631 is installed on the board 61 on which the driver circuit 4 is mounted and a receiving antenna 633 is installed on the board 63 on which the receiver circuit 5 is mounted. According to this embodiment, it is possible not only lengthen the distance of transmission through the signal transmission path, as is the case for the foregoing embodiment, but also transmit a signal at a higher rate by virtue of signal transmission by radio and move or relocate the boards freely.

### Embodiment 8

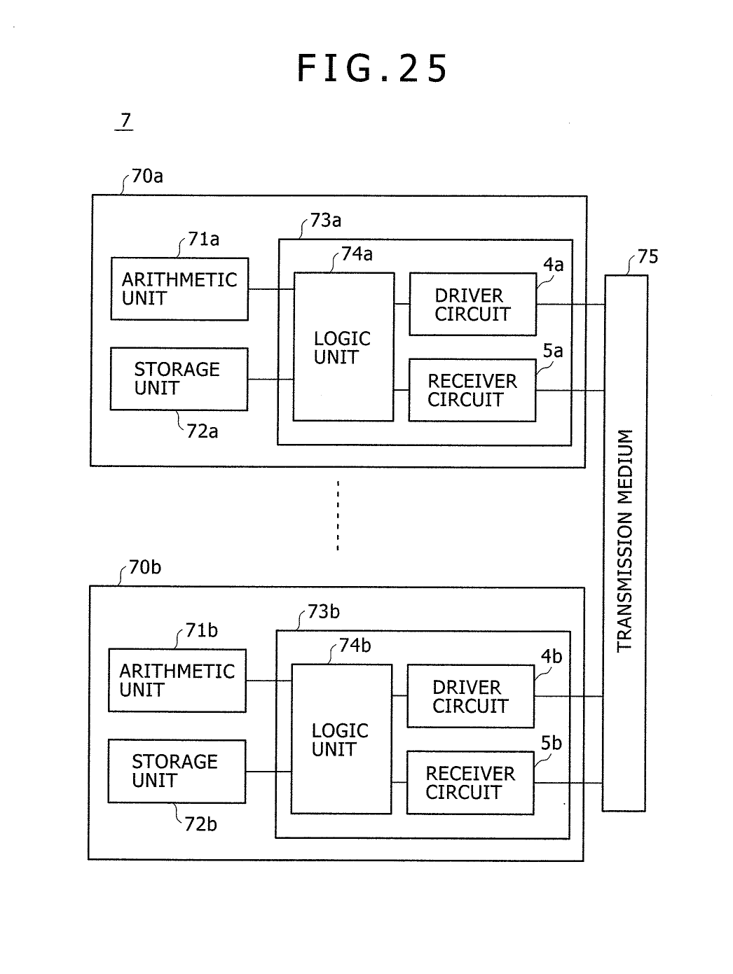

FIG. 25 is a configuration diagram showing one embodiment of a computing system 7 utilizing any signal transmission module 6 as described in the foregoing Embodiment 7. In this configuration, the computing system 7 includes a plurality of computers 70a, 70b, . . . and the computers 70 are interconnected via a transmission medium 75 so that one computer can transmit and receive data signals to/from another computer. Each computer 70 includes an arithmetic unit 71, a storage unit 72, and a data processing unit 73 and the data processing unit 73 includes a logic unit 74, a driver circuit 4 for transmitting data signals, and a receiver circuit 5 for receiving data signals. To provide the driver circuit 4, the receiver circuit 5, and the transmission medium 75, any signal transmission module 6 as described in the foregoing Embodiment 7 is used.

With the driver circuit 4 in the present embodiment, it is possible to improve the quality of transmission signals by suppressing delay time variation of signals transmitted through the transmission medium 75, as noted above. In consequence, the distance of transmission between each computer 70 can be lengthened and, thus, a larger scale computing system 7 having a high computing capacity can be built.

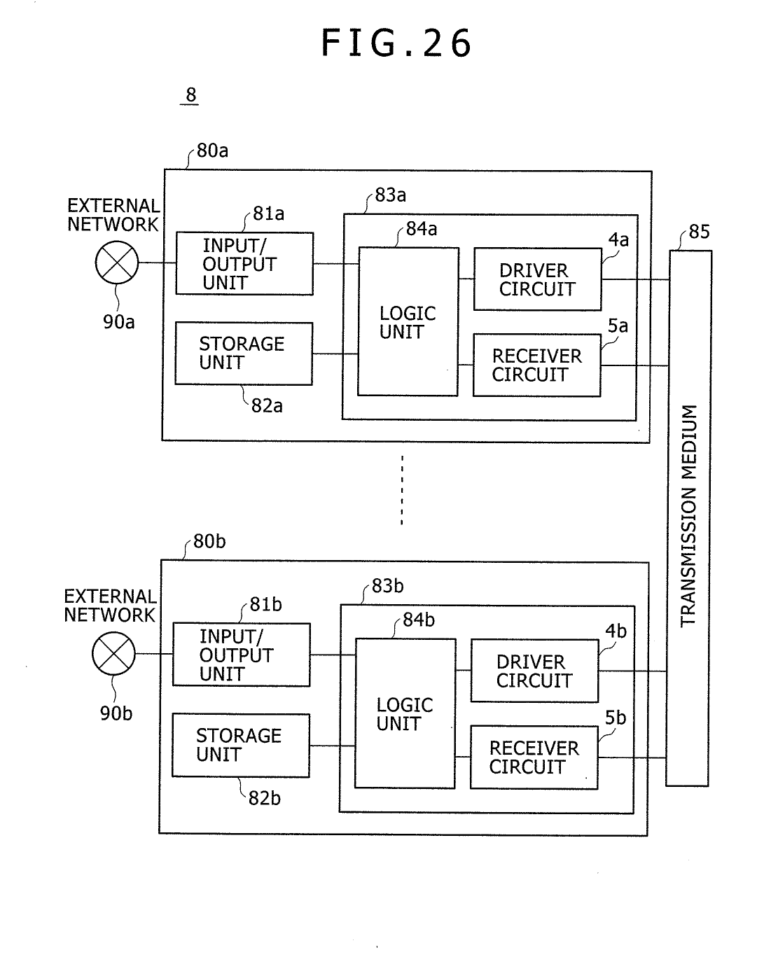

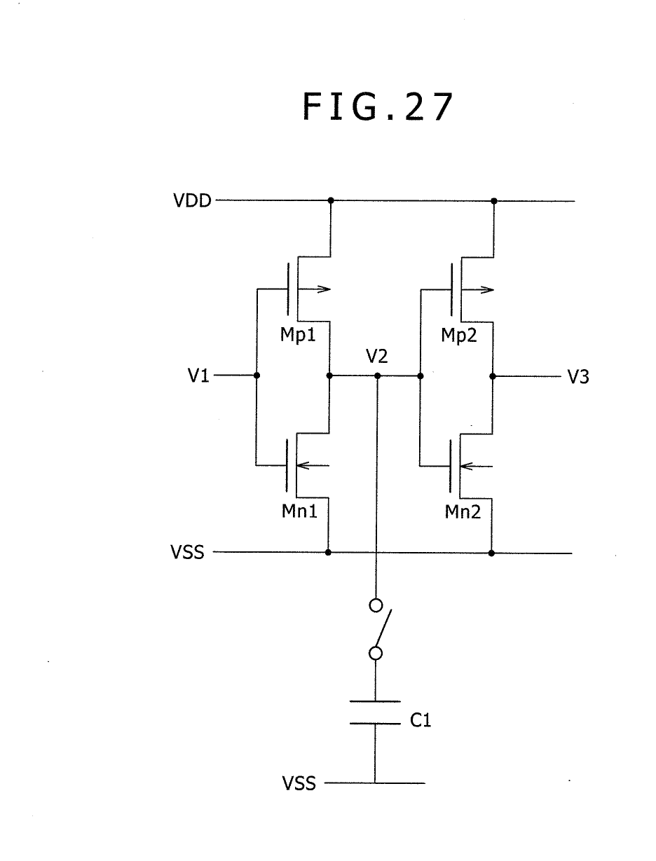

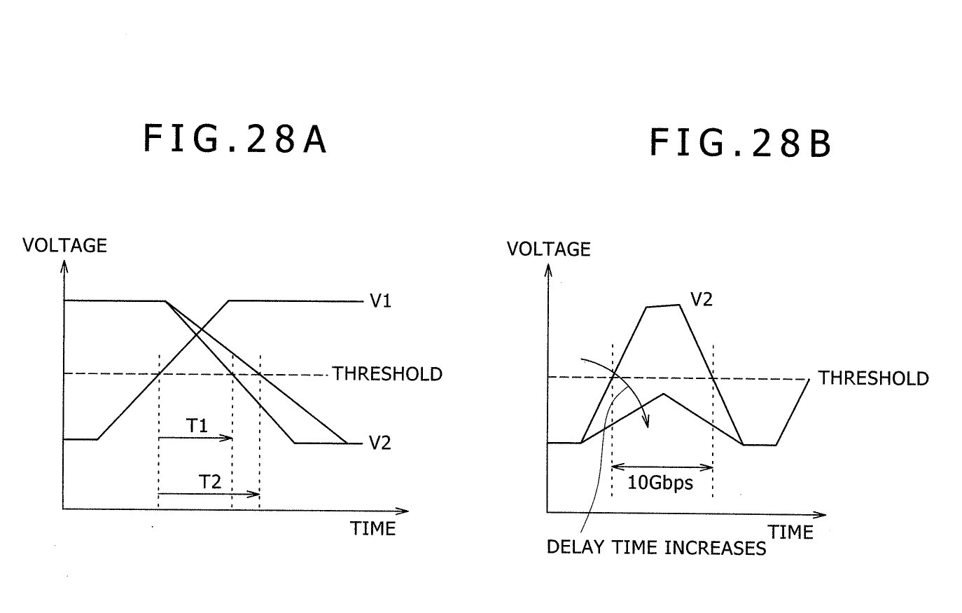

FIG. 26 is a configuration diagram showing one embodiment of a data exchange system 8 utilizing any signal transmission module 6 as described in the foregoing Embodiment 7. In this configuration, the data exchange system 8 includes a plurality of communication devices 80a, 80b, . . . which are connected to external networks 90a, 90b, respectively, and one device can transmit and receive data signals to/from another device via a transmission medium 85. Each communication device 80 includes an input/output unit 81 which is connected to one of the external networks 90a, 90b, a storage unit 82, and a data processing unit 83. The data processing unit 83 includes a logic unit 84, a driver circuit 4 for transmitting data signals, and a receiver circuit 5 for receiving data signals. To provide the driver circuit 4, the receiver circuit 5, and the transmission medium 85, any signal transmission module 6 as described in the foregoing Embodiment 7 is used.

According to this configuration, it is possible to improve the quality of signals transmitted through the transmission medium 85. In consequence, the distance of transmission between each communication device 80 can be lengthened and, thus, a larger scale data exchange system 8 that can accommodate an increasing number of network connections can be built.

### Embodiment 9

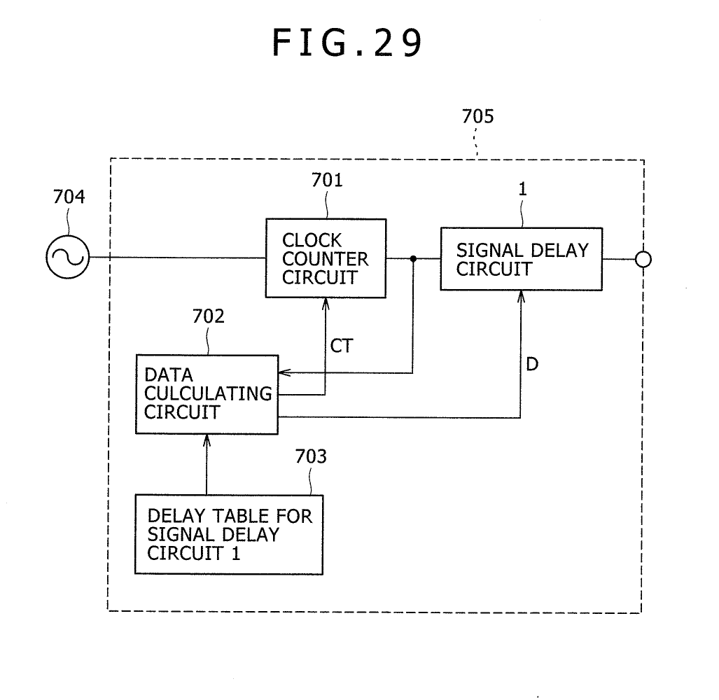

FIG. 29 is a configuration diagram showing one embodiment of an IC circuit with a pulse generating function utilizing a signal delay circuit according to the present invention. The IC circuit with the pulse generating function of the present embodiment is composed of a clock counter circuit 701, a data calculating circuit 702, and the signal delay circuit 1 as described in the foregoing Embodiment 2 (FIG. 5).

The data calculating circuit 702 outputs delay data CT and D to the clock counter circuit 701 and the signal delay circuit 1, respectively. The clock counter circuit 701 implements a delay that is an integral multiple of a master clock, based on the delay data CT. The signal delay circuit 1 implements a delay less than a master clock, based on the delay data D. Here, the delay adjustment range of the signal delay circuit should be wider than a delay of one master clock period.

The delay data D can be determined by a delay stored in a delay table 703 and, thus, an output pulse delay can be adjusted precisely.

Here, because the signal delay circuit 1 of the present invention implements the feedback resistance method, as noted above, it is possible to make a delay adjustment even for a signal with a short pulse width. The IC circuit with the pulse generating function of the present embodiment can output a signal with a shorter pulse width, as compared with a conventional IC circuit with the pulse generating function.

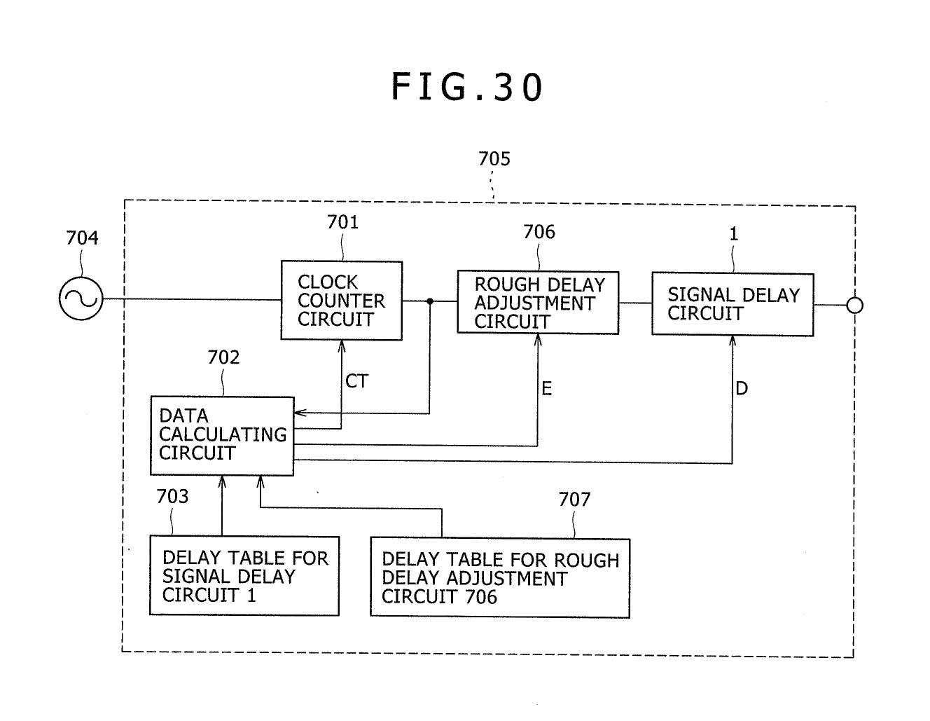

FIG. 30 shows a configuration of an IC circuit with a pulse generating function further including a rough delay adjustment circuit 706 added to the embodiment of FIG. 29. The delay adjustment range of the rough delay adjustment circuit 706 should be narrower than a delay of one master clock period. The delay adjustment range of the signal delay circuit 1 should be wider than the delay adjustment range of the rough delay adjustment circuit 706.

In this way, in the IC circuit with the pulse generating function shown in FIG. 30, the delay adjustment range that is covered by the signal delay circuit 1 can be decreased by adding the rough delay adjustment circuit 706. It is thus possible to make the circuit scale compact and suppress power consumption. Because the number of inverter stages in the signal delay circuit 1 can be reduced, a higher delay resolution can be achieved, if the same delay control method is used.

The IC circuit with the pulse generating function of the present invention is capable of outputting a signal with a shorter pulse width than ever before. Therefore, if this IC circuit is used in an IC tester or similar measuring instruments requiring high frequency pulses, a higher measurement frequency than ever before is achievable.

While the embodiments of signal delay circuits according to the present invention and oscillation circuits, driver circuits, signal transmission modules, a computing system, a data exchange system, and IC circuits with the pulse generating function using the signal delay circuits have been described in detail hereinbefore, these embodiments are only examples and some of such embodiments may be combined appropriately, and modifications thereto are possible within the scope of the gist of the present invention. Needless to say, besides the above embodiments, the present invention can be applied effectively to circuits and systems such as servers, routers, storages, and image processing devices that use a serial transmission technique mainly inside equipment. Furthermore, the technique of the present invention can be applied to signal transmission inside a commonly used communication device or to various types of measuring instruments requiring timing accuracy.

According to the present invention, a high-speed signal delay time can be adjusted continuously without degrading the signal quality. Delay time variation can be suppressed even if the power supply voltage is low.

The invention may be embodied in other specific forms without departing from the spirit of essential characteristics thereof. The present embodiments are therefore to be considered in all respects as illustrative and not restrictive, the scope of the invention being indicated by the appended Claims rather than by the foregoing description and all changes which come within the meaning and range of equivalency of the Claims are therefore intended to be embraced therein.

1. A signal delay circuit comprising a first inverter circuit and a second inverter circuit connected to an output terminal of the first inverter,
the signal delay circuit including a feedback circuit extending from an output terminal of the second inverter circuit to an input terminal of the second inverter circuit,
wherein a delay time of the first inverter circuit is adjusted by controlling the amount of feedback through the feedback circuit.

2. The signal delay circuit according to claim 1,
wherein: the first and second inverter circuits are formed by CMOS transistors;
the feedback circuit is formed by MOS transistors; and
the delay time of the first inverter circuit is adjusted by controlling gate voltages of the MOS transistors, thus controlling the amount of feedback through the feedback circuit.

3. The signal delay circuit according to claim 1, further comprising a control circuit for controlling the feedback circuit,
wherein the control circuit adjusts the amount of feedback through the feedback circuit in relation to a variation in a power supply voltage and suppresses a variation in the delay time of the signal delay circuit.

4. An oscillation circuit including a plurality of signal delay circuits connected in series, whose output is fed back to an input terminal of the oscillation circuit,
each the signal delay circuit comprising: a first inverter circuit; a second inverter circuit connected to an output terminal of the first inverter; and a feedback circuit extending from an output terminal of the second inverter circuit to an input terminal of the second inverter circuit,
wherein, by controlling the amount of feedback through the feedback circuit, a delay time of each the signal delay circuit is adjusted and an oscillation frequency of the oscillation circuit is controlled.

5. The signal delay circuit according to claim 3,
wherein: the control circuit includes an oscillation circuit whose oscillation frequency changes according to the power supply voltage and adjusts the amount of feedback through the feedback circuit in relation to the oscillation frequency; and
the oscillation circuit comprises a second signal delay circuit whose delay time changes depending on the power supply voltage, wherein output of the second signal delay circuit is fed back to an input terminal of the oscillation circuit.

6. A driver circuit that transmits a signal, while adjusting timing to output the signal, the driver circuit comprising:
a timing adjustment circuit that adjusts transmission timing; and
a signal delay circuit that adjusts a delay time of a signal from the timing adjustment circuit,
the signal delay circuit including: a first inverter circuit; a second inverter circuit connected to an output terminal of the first inverter; and a feedback circuit extending from an output terminal of the second inverter circuit to an input terminal of the second inverter circuit,
wherein a delay time of the signal to be transmitted is adjusted by controlling the amount of feedback through the feedback circuit.

7. A driver circuit comprising a plurality of driver paths, each comprising the driver circuit according to claim 6,
wherein a delay time of a signal delay circuit in each driver circuit is adjusted to eliminate a time difference between signals on the plurality of driver paths to be transmitted.

8. A signal transmission module comprising a driver circuit mounted on a circuit board and a receiver circuit mounted on a circuit board, a signal being transmitted from the driver circuit to the receiver circuit via a signal transmission path,
the driver circuit including a signal delay circuit that adjusts a delay time of a signal to be transmitted and the signal delay circuit including: a first inverter circuit; a second inverter circuit connected to an output terminal of the first inverter; and a feedback circuit extending from an output terminal of the second inverter circuit to an input terminal of the second inverter circuit,
wherein a delay time of a signal to be transmitted through the signal transmission path is adjusted by controlling the amount of feedback through the feedback circuit.

9. A computing system comprising a plurality of computers interconnected via a transmission medium, wherein one computer can transmit and receive data signals to/from another computer,
each computer having: an arithmetic unit; a storage unit; a logic unit; a driver circuit for transmitting data signals; and a receiver circuit for receiving data signals,
the driver circuit including a signal delay circuit that adjusts a delay time of a data signal to be transmitted,
the signal delay circuit having: a first inverter circuit; a second inverter circuit connected to an output terminal of the first inverter; and a feedback circuit extending from an output terminal of the second inverter circuit to an input terminal of the second inverter circuit,
wherein a delay time of a signal to be transmitted through the transmission medium is adjusted by controlling the amount of feedback through the feedback circuit.

10. A data exchange system comprising a plurality of communication devices interconnected via a transmission medium, wherein one device can transmit and receive data signals to/from another device,
each communication device having: an input/output unit that is connected to an external network; a storage unit; a logic unit; a driver circuit for transmitting data signals; and a receiver circuit for receiving data signals,
the driver circuit including a signal delay circuit that adjusts a delay time of a data signal to be transmitted,
the signal delay circuit having: a first inverter circuit: a second inverter circuit connected to an output terminal of the first inverter: and a feedback circuit extending from an output terminal of the second inverter circuit to an input terminal of the second inverter circuit,
wherein a delay time of a signal to be transmitted through the transmission medium is adjusted by controlling the amount of feedback through the feedback circuit.

11. An IC circuit with a pulse generating function operating in synchronization with a master clock, comprising:
a data calculating circuit that generates a pulse at desired intervals or a pulse delayed by a desired time from a reference signal;
a clock counting circuit that counts an integral multiple of a master clock and generates a pulse according to first data from the data calculating circuit;
a pulse delay circuit that produces a delay according to second data from the data calculating circuit; and
a delay table that stores a delay produced by the pulse delay circuit,
wherein the IC circuit with the pulse generating function includes the signal delay circuit according to claim 1 as the pulse delay circuit.
